(19) United States
(12) Patent Application Publication
(10) Pub. No.: US 2019/0335542 A1
(43) Pub. Date: Oct. 31, 2019

(54) MAT USING INFRARED LEDS

(71) Applicants: JOY COMMERCE CO., LTD., Cheonam-city (KR); AIMQ CO., LTD., Gunpo-si (KR)

(72) Inventors: Kwang Sig LEE, Daedeok-gu (KR); Joo Young HUR, Ansan-city (KR)

(21) Appl. No.: 16/381,949

(22) Filed: Apr. 11, 2019

(30) Foreign Application Priority Data
Apr. 26, 2018 (CN) 201810383648.X

(51) Int. Cl. H05B 3/00; H01L 33/62; A47G 27/04

(52) U.S. Cl. CPC H05B 3/0071; H01L 33/62; A47G 2200/16; H05B 2203/032; H05B 2203/026; A47G 27/0406

(57) ABSTRACT

A mat using infrared LEDs comprising an infrared LED aluminum package (3), a temperature controller (2) supplying a power supply to an infrared LED chip (13), a FPCB (flexible printed circuit board) having the infrared LED aluminum package (3) mounted therein and including a terminal connecting the infrared LED aluminum package (3) to a wire, and a base sheet (6) for dispersing heat. According to the mat using infrared LEDs, aluminum with high thermal conductivity better radiates heat, the infrared light emitted from the LED is helpful for treatment and health improvement, the thin thickness of the infrared LED aluminum package prevents discomfort when a user lies thereon and the mat which is light in weight is easily movable or rollable for storage.

### BACKGROUND OF THE INVENTION

### Field of the Invention

The present invention relates to a mat using infrared LEDs, and more particularly, to an electronic mat using infrared LED aluminum packages.

### Description of the Related Art

In general, far infrared light has wavelengths of 24 μm or more, near infrared light has wavelengths of 750 nm (0.75 μm)˜3 μm, and just infrared light means the middle range between the far infrared light and near infrared light. An infrared LED means an infrared emitting diode (IRED), which emits infrared light invisible to the eyes of a human. Infrared LEDs include an infrared LED with a wavelength to use a remote controller and an infrared LED to be used as an auxiliary light of a night vision goggle. Infrared LEDs are mainly used for an IR emitter, a TV remote controller, an optical switch, an IR LAN, a module for wireless digital data communication, etc.

Further, the research results in which infrared light emitted from LEDs is effective for treating an inflammation or skin disease have been published. In many cases, a red light lamp is applied to an ear or eye for treatment in an ear-nose-and throat clinic (otolaryngology) or ophthalmic clinic, from the concept that an affected area is treated by expanding blood vessels by using the heat of infrared light. LEDs, which are widely used as lighting as described above, have been recognized as a major light source of phototherapeutic treatment.

An LED as a semiconductor which emits light when current is applied has advantages of being capable of emitting all light, such as ultraviolet light, visible light, infrared light, etc., and controlling the output and color of light. Further, since LEDs have low energy consumption and are able to emit only light with a desired wavelength and therefore, side effects are small and no damage is caused to any other tissues of a human body, LEDs are proper for use in medical apparatuses. Based on these grounds, the US Food and Drug Administration (FDA) allows the use of LEDs in the regions of the visible and near infrared light, for human body treatment.

The aforementioned effects of LEDs result since the light is absorbed by the photoreceptors inside cells, to promote the activity of enzymes. Further, the light promotes the activity of mitochondria which provides energy to the cells, so that the movement of cells generally becomes active.

In general, a far infrared heat treatment mat, which has been used at home and abroad, is structured to have a heat generating electric wire and a plate which is made of a material to generate far infrared light and which is placed on the heat generating electric wire. Lately, a sheet heating unit has been developed for use by weaving a fabric with a far infrared light generating material and a very fine heat generating electric wire and applying electricity to the fabric to emit far infrared light. Recently, a carbon heating unit from which far infrared light is directly emitted, without any electric heating wire, has been used. In this case, although it is convenient since far infrared light is directly emitted without electric wires, its cost is high and thus the carbon heating unit is usually reserved for use in an expensive product. Far infrared light, which is used for a whole body heat treatment apparatus for a hospital, is emitted by electrically heating an outer wall of a heating container after coating an inner wall of the heating container with a special ceramic. The use of the forgoing method enables far infrared light to attain a high temperature, however, since such a heating apparatus is very big, it is difficult to be used in the home. In addition, there is a method for heating a whole body by circulating hot water. In the case of using water, the structure is complicated due to a water-proof problem.

Korean Patent No. 10-1394561 (Registration Date: May 7, 2014; “Patent Document 1”) relates to a heating mat utilizing LEDs, which comprises: an electro thermal wire generating electric heat, a far infrared emitter including red clay and a number of LEDs. In Patent Document 1, the heating mat includes mood lighting or household lighting by emitting the light of LEDs, providing practicability, convenience and decorative features. Further, this heating mat significantly doubles the amount of emission, providing an effect of improving health.

Korean Utility Model No. 20-0326019 (Registration Date: Aug. 29, 2003; “Patent Document 2”) relates to a skin and physical therapy treatment apparatus using an LED, a laser diode (LD) and infrared (IR) lamp. In Patent Document 2, the apparatus has a feature of providing an infrared treatment effect and an heating effect by overcoming the disadvantages of the previous laser treatment apparatus which is high in price but low in efficiency and using an infrared lamp, unlike the previous treatment apparatus using the LED and LD. This apparatus uses both LED and IR. This apparatus is used for an affected/topical area only and cannot be used for a whole body unlike a mat.

Korean Published Application No. 2002-0035819 (Publication Date: May 15, 2002; “Patent Document 3”) relates to an LED matrix module using a reflector plane capable of functioning as a radiator plate, and a method of forming the same. According to the abstract of Patent Document 3, the LED matrix module and the method of forming the same have a radiation and reflection structure in which a reflector plane, which provides a path to outwardly reflect the light emitted from a light emitting device, such as a LED in the form of a chip on board (COB), a ground pattern formed on a substrate to which the LED is mounted, and a resin filling the path to perform a role of heat conduction. To this end, in the invention of Patent Document 3, the reflector plane and the ground pattern are made of metals or materials coated with metals which have good heat conductivity. Further, the heat conductive transparent resin filling the path of the light makes for better heat conductivity and light transmissibility. Once the radiator and reflector structure covers a circuit board, the radiator structure is naturally connected when the LED matrix module is connected, enabling natural air cooling or forced air cooling of heat emission. Therefore, when the LED in the form of COB is mounted, the invention not only transmits the light effectively but also effectively radiates and forms a dust-free and water-proof structure.”

Korean Patent No. 10-1076471 (Registration Date: Oct. 18, 2011; “Patent Document 4”) relates a bed mat using the light of an LED, which maximizes an effect of improving health and provides conformable and pleasant bed life. In Patent Document 4, a light emitting sheet comprises an LED which radiates light and emits far infrared light or anions. After a plurality of housings, which are structured such that each of the LEDs is adhesively held in an insertion hole formed on the light emitting sheet or is forcibly press-fitted in the insertion hole, are temporarily adhered to the top of a lower material by using an adhesive, the LED, housing and some of electric power supply wires connected to the housing are covered with a silicon adhesive, to be sealed to be individually attached to the lower material. In Patent Document 4, no constitution of using the warm heat of the LED is disclosed.

The electronic mats according to the aforementioned patent documents and the previous electronic mats are not capable of sufficiently showing the effects of LEDs. Therefore, since the LEDs having a large capacity are used, if any LED protrudes, it causes a sore to a user. Since the thickness of an LED is thick and its weight is heavy, it is inconvenient to be moved and it is impossible to be rolled like a scroll for storage. Moreover, since an adhesive is used to secure an LED to a lower plate, it is harmful to the human body.

### RELATED ART DOCUMENTS

### Patent Documents

Patent Document 1: Korean Patent No. 10-1394561 (Registration Date: May 7, 2014)

Patent Document 2: Korean Utility Model No. 20-0326019 (Registration Date: Aug. 29, 2003)

Patent Document 3: Korean Published Application No. 2002-0035819 (Publication Date: May 15, 2002)

Patent Document 4: Korean Patent No. 10-1076471 (Registration Date: Oct. 18, 2011)

### SUMMARY OF THE INVENTION

An object of the present invention is to provide a mat using infrared LEDs, wherein the mat is heated by using radiation from the LEDs and simultaneously treatment or health improvement is performed by using infrared light emitted from the LEDs.

Another object of the present invention is to provide a mat using infrared LEDs, wherein since an effective heat emission is performed by using infrared LED aluminum packages, a thermal runway phenomenon is prevented to greatly increase the life span of the infrared LED, and since heat being generated is effectively transmitted to a flexible printed circuit board (FPCB) so that the heat is overall evenly spread, a heating function is provided.

Another object of the present invention is to provide a mat using infrared LEDs, wherein the mat is thin in thickness and light in weight so that it is easily moved and stored.

In accordance with the present invention, a mat using infrared LEDs may comprise: an infrared LED aluminum package; a temperature controller supplying electrical power to an infrared LED chip; a FPCB (flexible printed circuit board) having the infrared LED aluminum package mounted therein and including a terminal connecting the infrared LED aluminum package to a wire; and a base sheet for dispersing heat. The infrared LED aluminum package comprises: two pieces of aluminum sheets connected together; an insulator inserted between the two pieces of the aluminum sheets; a recess in a frustoconical shape formed at one side of the connected aluminum sheets, the recess including a slope side reflection surface of the frustoconical shape and a bottom reflection surface on which the infrared LED chip is positioned; a silicon-filled portion to pack the infrared LED chip and the FPCB sealing an electric connection member, wherein the angle of radiation of the reflection surface is freely set between 20°˜60° based on the size of the infrared chip and the purpose of use, the reflection surface is coated with silver or chrome and the silicon-filled portion has a concave lens functioning as a lens to control the angle of radiation of the infrared LED chip.

In a preferable embodiment of the present invention, the mat uses a material and thickness to be rollable like a scroll.

In a further preferable embodiment, the mat has the entire thickness of 1 cm or less.

In a further preferable embodiment, the LED aluminum packages are arranged to be spaced apart from one another, by about by 1 to 10 cm by 1 to 10 vertically and horizontally, on the mat.

In a further preferable embodiment, the mat has a maximum temperature to be controllable within 50° C.˜55° C.

In a further preferable embodiment, the mat further comprises a temperature controller, which is a DC type separated to the outside.

### Advantageous Effects of the Invention

According to the mat using infrared LEDs of the present invention which comprises the infrared LED aluminum packages, the wires connecting the infrared LED aluminum packages in parallel and in series, the flexible printed circuit board (FPCB) having the infrared LED aluminum packages mounted therein and sealing the infrared LED aluminum packages and the wires, and the base sheet structured to disperse the heat, aluminum with high thermal conductivity better radiates heat, the infrared light emitted from the LED is helpful for treatment and health improvement, the thin thickness of the infrared LED aluminum package prevents discomfort when a user lies thereon, and the mat which is light in weight is easily movable or rollable for storage.

### BRIEF DESCRIPTION OF THE DRAWINGS

FIG. 1 is a sectional view of an infrared LED aluminum package applied to a mat according to a preferable embodiment of the present invention;

FIG. 2 is a circuit diagram of the arrangement of infrared LEDs and flexible printed circuit boards (FPCBs) wherein the infrared LEDs are mounted according to a preferable embodiment of the present invention; and

FIG. 3 is a perspective view of a layer structure of the mat according to the present invention.

### DETAILED DESCRIPTION OF THE PREFERABLE EMBODIMENTS

Hereinafter, the embodiments of the present invention will be described in detail with reference to the accompanying drawings so that those skilled in the art can easily practice the present invention. Integer

[symbol]

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, element, components, and/or groups thereof.

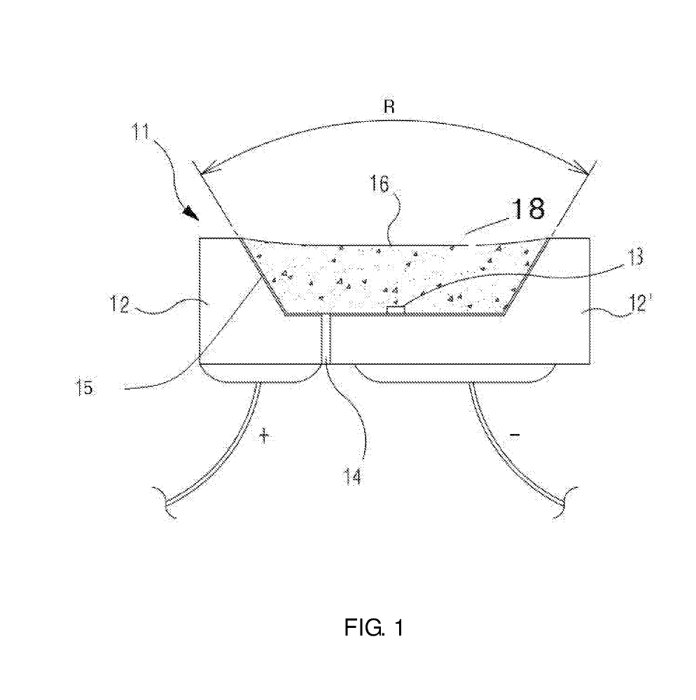

FIG. 1 shows a terminal 11 of an LED package. The LED package is made by connecting two pieces of aluminum sheets 12, 12′ as shown. An insulator 14 is inserted between the two pieces of the aluminum sheets 12, 12′. A recess 18 in a frustoconical shape is formed between the two pieces of the aluminum sheets 12, 12′. The recess 18 includes a slope side reflection surface 15 of the frustoconical shape and a bottom reflection surface on which a infrared LED chip 13 is positioned. To increase reflection efficiency, the aluminum side is coated with silver or chrome.

Since aluminum has a thermal conductivity of 201 W/mk, when aluminum is used for the LED package, the radiation effect is high. The infrared LED chip 13 is positioned to be mounted onto an electrode exposed on the bottom of the recess 18. Since the two aluminum sheets 12, 12′ are insulated by the insulator 14, a bonding wire is used to be electrically connected to the other electrode than the electrode connected to the infrared LED chip 13. The recess 18 is of a frustoconical shape with the diameter being wider towards the top and narrower towards the bottom. The diameter of the side refection surface 15 of the recess 18 is bigger towards the top and forms a radiation angle R of the LED infrared light. The angle of the reflection surface, that is, the radiation angle may change based on the size or capacity of the infrared LED chip. The reflection surface may be coated with silver or chrome to improve the reflectance.

Further, the recess 18 is generally sealed with light transmitting resins, to seal for moisture-proof of the infrared LED chip 13. In the present invention, the recess 18 is filled with light transmitting silicon. The silicon-filled part seals the infrared LED chip 13 and secures a connection wire. The silicon-filled part also functions as a lens to outwardly radiate the infrared light generated from the infrared LED chip 13.

In a preferred embodiment, the silicon-filled part has a concave lens 16 with one surface being flat and the other being concave, to radiate the infrared light which is reflected from the reflection surface 15.

In the preferred embodiment, the concave lens has a radiation angle of the reflection surface which is 20°˜60°.

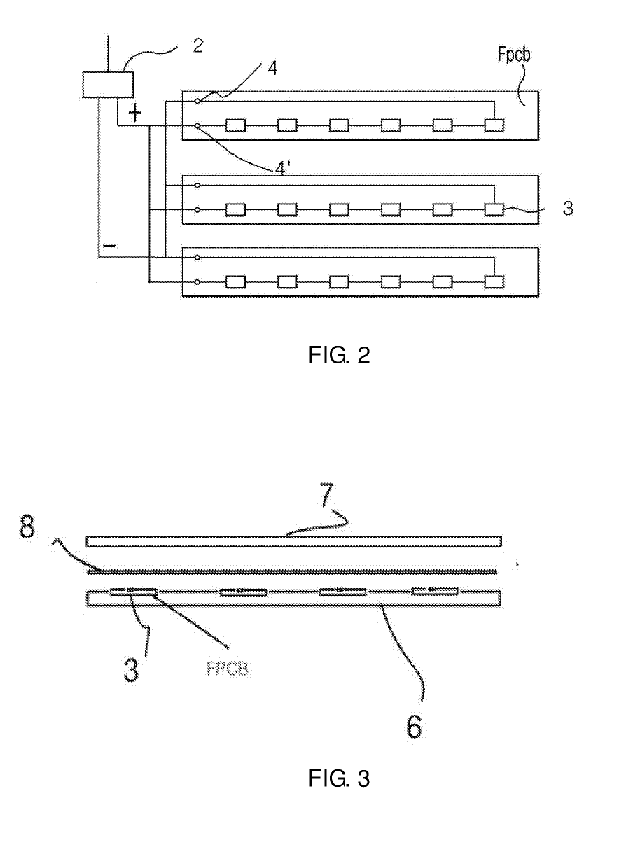

FIG. 2 is a circuit diagram of the mat using the infrared LEDs according to the present invention. The infrared LEDs are arranged, spaced apart from one another about by 1 to 10 cm by 1 to 10 vertically and horizontally, in the mat. The infrared LEDs are connected to one another in parallel vertically and in series horizontally. A positive (+) wire from a DC temperature controller 2 connected to a power line is connected to a positive (+) wire 4 on a flexible printed circuit board (FPCB), and a negative (−) wire from the DC temperature controller 2 is connected to a negative (−) wire 4′ on the FPCB, so that when the DC temperature controller 2 turns “ON”, the infrared light of an infrared LED aluminum package 3 radiates through the reflection surfaces. FIG. 2 shows some LEDs only, however, the number of LEDs and the number the serial-parallel structures may vary based on the dimension of the mat. As shown, the infrared LED aluminum packages 3 are mounted to the FPCB, which are processed with thin film materials, such as silicon, etc., for water-proofing and moisture-proofing. The DC temperature controller 2 is used by converting AC to DC, preventing the generation of electric waves.

The FPCB, an electronic component which has been developed according to the trends of small and light electronic products, has high operating efficiency, high thermal resistance, high folding endurance, high chemical resistance. Since the FPCB is strong against heat, it sufficiently endures the radiation from the infrared LEDs and does not cause any problems at a temperature of 70° C. or higher. Since the FPCB has high durability at repetitive folding, it is used for the mat of the present invention, enabling the mat to be folded or rolled.

With reference to FIG. 3, the infrared LED aluminum packages 3 according to the present invention are mounted to the FPCBs and the FPCBs processed for water-proofing and moisture-proofing are inserted and fixed in a groove formed on a base sheet 6 of the mat by an adhesive, etc. A material, such as a non-woven fabric 8, which has the area corresponding to the area of the base sheet 6, is positioned on the FPCBs with the infrared LED aluminum packages 3, to further secure and cover the FPCBs and prevent a top fabric 7 from discoloring by infrared light. The non-woven fabric 8 may be additionally positioned between the base sheet 6 and the FPCBs. The top fabric 7 which is soft and is directly in touch with a human body is positioned on the non-woven fabric 8. Since the heat from the LEDs is radiated through the aluminum and the base sheet 6, the base sheet 6 has the material or structure to better disperse the heat. The maximum temperature of heating of the mat is controllable up to 50° C.˜55° C., without any other heat source. When the temperature of the heat is higher than 55° C., the life-span of the infrared LED chip is shortened. At 50° C., a user feels warm and can usually use the mat for six (6) hours, with ease, which time the user can sleep. The base sheet 6 uses a foldable or rollable material. PVC is high in shock-proof and PE which is lighter than PVC is easily movable and highly utilized. At least an organic polymer compound or cellulose may be used for the base sheet 6. Preferably, the thickness of the base sheet 6 may be 5 mm or less. Preferably, the top fabric 7 which is directly in touch with a human body may be made of environment-friendly materials. Further preferably, the non-woven fabric 8 may be made of materials enabling moisture absorption and heat generation.

Since the thickness of the infrared LED aluminum package 3 is thin as about 1.05 mm, even if it is perfectly received in the groove of the base sheet 6 or slightly protrudes, it is almost flat and therefore a user does not feel any pressure or discomfort by the infrared LED aluminum packages 3 upon lying on the mat. Thus, the mat is manufactured in the form of a general mat.

When the entire thickness of the mat is under 1 cm, it is easily rollable like a scroll.

The invention has been described using a preferred exemplary embodiment(s). However, it is to be understood that the scope of the invention is not limited to the disclosed embodiment(s). On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A mat using infrared LEDs, comprising:
an infrared LED aluminum package;
a temperature controller supplying electrical power to an infrared LED chip;
a FPCB (flexible printed circuit board) having the infrared LED aluminum package mounted therein and including a terminal connecting the infrared LED aluminum package to a wire; and
a base sheet for dispersing heat,
wherein the infrared LED aluminum package comprises:
two pieces of aluminum sheets connected together;
an insulator inserted between the two pieces of the aluminum sheets;
a recess in a frustoconical shape formed at one side of the connected aluminum sheets, the recess including a slope side reflection surface of the frustoconical shape and a bottom reflection surface on which the infrared LED chip is positioned; and
a silicon-filled portion to pack the infrared LED chip and the FPCB sealing an electric connection member,
wherein the angle of radiation of the reflection surface is freely set between 20°˜60° based on the size of the infrared chip and the purpose of use, the reflection surface is coated with silver or chrome, the silicon-filled portion has a concave lens functioning as a lens to control the angle of radiation of the infrared LED chip, and the maximum temperature of heat of the mat is controllable up to 50˜55° C., without any other heat source.

2. The mat using infrared LEDs according to claim 1, wherein the material and thickness of the base sheet are selected to be rollable like a scroll.

3. The mat using infrared LEDs according to claim 1, wherein the DC temperature controller is a DC type separated to the outside.

4. The mat using infrared LEDs according to claim 1, wherein the infrared LED aluminum packages are arranged to be spaced apart from one another, about by 1 to 10 cm by 1 to 10 vertically and horizontally, and the mat is under 1 cm in the entire thickness.
